(19) United States
(12) Patent Application Publication
(10) Pub. No.: US 2014/0091229 A1
(43) Pub. Date: Apr. 3, 2014

(54) ELECTRODE FOR A CHARGED PARTICLE BEAM LENS

(71) Applicant: Kazushi Nomura, Sagamihara-shi (JP)

(72) Inventor: Kazushi Nomura, Sagamihara-shi (JP)

(21) Appl. No.: 14/119,217

(22) PCT Filed: May 17, 2012
(86) PCT No.: PCT/JP2012/063235

§ 371 Date: Nov. 21, 2013

(30) Foreign Application Priority Data
Jun. 23, 2011 (JP) 2011-139965

(51) Int. Cl. H01J 37/12

(52) U.S. Cl. CPC H01J 37/12
USPC 250/396 R

(57) ABSTRACT

An electrode to be used for an electrostatic charged particle beam lens includes at least one through hole. The at least one through hole includes a first region having a first opening contour and a second region having a second opening contour to be positioned on an upstream side of a charged particle beam with respect to the first region, The first opening contour is included in the second opening contour when viewed in an optical axis direction.

This application claims the benefit of Japanese Patent Application No. 2011-139965, filed Jun. 23, 2011, which is hereby incorporated by reference herein in its entirety.

### TECHNICAL FIELD

The present invention relates to a charged particle beam optical system used for charged particle beam exposure equipment, such as electron beam exposure equipment or ion beam exposure equipment, which are used for exposure of a semiconductor integrated circuit, or the like. In particular, the present invention relates to an electrode for an electrostatic lens (typically, an electrode for an electrostatic objective lens).

### BACKGROUND ART

As exposure equipment for exposing patterns in which fine patterns having a width of 0.1 micrometers or less are packed at high density, the electron beam exposure equipment is quite prospective. In particular, an electron beam exposure equipment that is capable of patterning with multiple electron beams, simultaneously, without using a photomask is quite prospective because it can support flexible production with high throughput. When the electron beam is used for patterning, however, chemical substances of a resist, or the like, at the spot irradiated by the electron beam may be scattered, and hence, it is inevitable that the resist, or the like, adheres to lenses, particularly, to an objective lens closest to a sample (object). This adhesion of the resist, or the like, causes deterioration of optical characteristics of the lens, and is apt to be an obstacle for long-term use.

In order to solve this problem, Japanese Patent No. 3166946 discloses the following electron beam exposure equipment. Specifically, this apparatus includes a conductive pi ate having an electron beam passage between the sample and an electron beam focusing objective lens or a beam deflector. With this structure, it is possible to prevent an evaporated substance of the sample, reflected electrons, and secondary electrons from entering the electron beam passage formed by the electron beam focusing objective lens and the beam deflector.

### SUMMARY OF THE INVENTION

### Technical Problem

In the field of semiconductor devices, finer patterning is required, and at the same time, high resolution exposure equipment is demanded so as to realize the finer patterning. In order to respond to this demand, if the resolution of the exposure equipment is increased, the distance between the objective lens and the sample becomes smaller. In the conventional example disclosed in Japanese Patent No. 3166946, the conductive plate is disposed for preventing the evaporated substance of the sample, or the like, from entering the objective lens, as described above. When the distance between the objective lens and the sample becomes smaller, however, it may be physically difficult to dispose the conductive plate properly.

### Solution to the Problem

In view of the above-mentioned problem, an electrode of the present invention to be used for an electrostatic charged particle beam lens includes at least one through hole. The at least one through hole includes a first region having a first opening contour and a second region having a second opening contour to be positioned on an upstream side of a charged particle beam with respect to the first region. The first opening contour is included in the second opening contour when viewed in an optical axis direction.

### Advantageous Effects of the Invention

According to the electrode of the present invention, the opening contour of the first region is included in the opening contour of the second region when viewed in the optical axis direction, and hence, a scattered substance, or the like, of an object is blocked by the first region so as to hardly reach the second region and a region closer to a charged particle source with respect to the second region. Therefore, it is possible to realize the electrode in which the scattered substance or the evaporated substance of the object can hardly reach the second region and a region closer to the charged particle source with respect to the second region. In addition, it is not necessary to dispose an additional shield plate, or the like, and hence, the space between the lens including the electrode and the object can be decreased.

Further features of die present invention will become apparent from the following description of exemplary embodiments with reference to the attached drawings,

### BRIEF DESCRIPTION OF THE DRAWINGS

FIGS. 1A and 1B are diagrams illustrating an electrode of a charged particle beam objective lens according to a first embodiment of the present invention.

FIGS. 2A and 2B are cross-sectional views illustrating an electrostatic charged particle beam objective lens according to a second embodiment of the present invention, and a charged particle beam objective lens and its vicinity of exposure equipment according to a third embodiment of the present invention, respectively.

FIGS. 3A and 3B are diagrams illustrating patterns in a case in which internal diameter contours as the opening contours of first and second regions of the electrode are projected to the object, and a through hole and its vicinity of the electrode, respectively.

FIG. 4 is a diagram illustrating a multi-charged particle beam exposure equipment according to a fourth embodiment of the present invention.

FIGS. 5A, 5B, and 5C are diagrams illustrating various variation forms of the electrode according to the first embodiment of the present invention.

### DESCRIPTION OF THE EMBODIMENTS

An electrode of the present invention has a teal are that a through hole tor transmitting a charged particle beam is formed so that a first opening contour of the through hole on the downstream side is included in a second opening contour of the through hole on the upstream side, when viewed in the optical axis direction. The charged particle beam propagates along the optical axis at substantially the center of the through hole from the upstream side to the downstream side, and irradiates the object. In this action, a scattered substance, or the like, is likely to enter the electrode. By setting the first opening contour on the downstream side to be smaller than the second opening contour on the upstream side, it is possible to prevent scattered substances, or the like, from entering. What degree to set the first opening contour on the downstream side smaller is appropriately designed, in accordance with how to use the electrode or a specification of the electrode. In the present invention, the phrase “along the optical axis” includes the phrase “substantially along the optical axis”. In other words, this includes not only the case of being strictly aligned with the optical axis, but also, the case of being regarded as being substantially along the optical axis, even if deviated within an error range.

Hereafter, embodiments of the present invention are described. However, dimensions, materials, shapes, relative positions, and the like, of components described in the following embodiments should not be interpreted as limiting the present invention, unless otherwise noted.

### First Embodiment

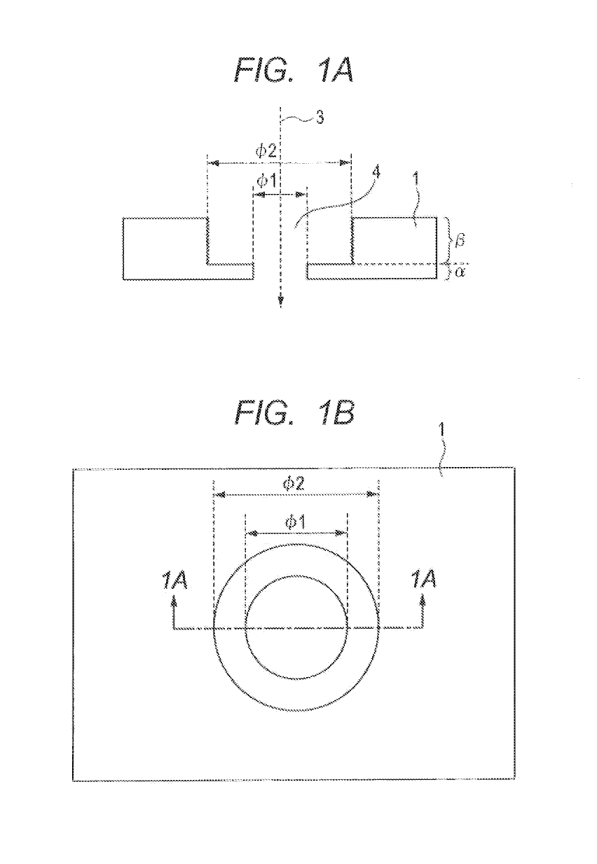

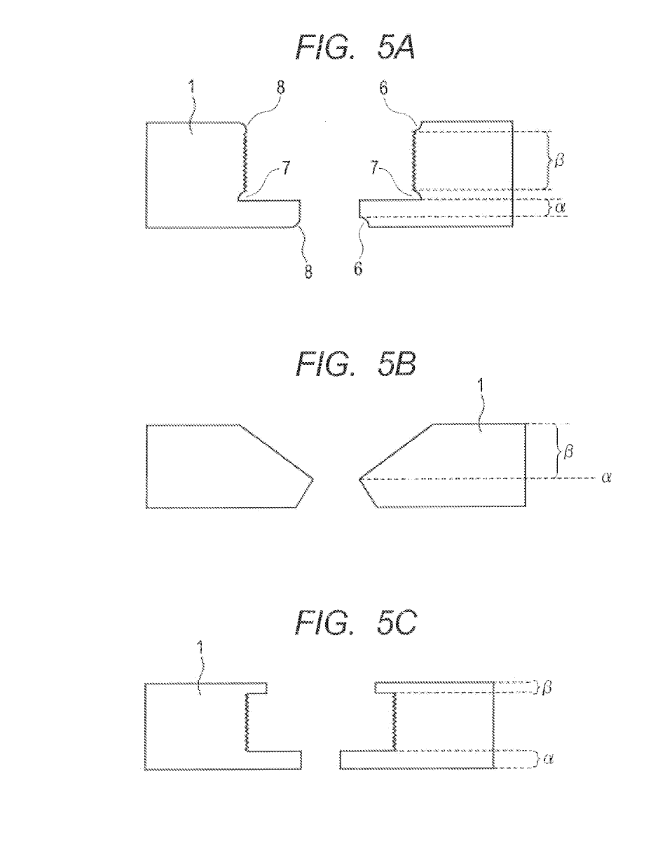

With reference to FIGS. 1A and 1B and FIGS. 5A to 5C, a first embodiment of she present invention is described, FIG. 1B is a schematic top view of an electrode closest to an object to be irradiated by a charged particle beam, which is used for a charged particle beam objective lens, FIG. 1A is a schematic cross-sectional view taken along the line 1A-1A of FIG. 1B.

As illustrated in FIG. 1A, in this embodiment, an electrode 1 closest to the object to be irradiated by the charged particle beam is a flat plate having an optical axis 3 as the normal, and has a through hole 4, This through hole 4 has a circular cross section, which includes a first region α having a first internal diameter φ1 and a second region β having a second internal diameter φ2. The relationship between those internal diameters is φ2>φ1. The second region β having the relatively larger internal diameter is positioned on the side closer to a charged particle source as a light source (not shown), namely, an upstream side of the charged particle beam, with respect to the first region α having the relatively smaller internal diameter.

In other words, the first region having the relatively smaller internal diameter has a shield plate structure, which has a function of preventing scattered substances, evaporated substances, or the like, of a sample as the object to be irradiated by the charged particle beam from entering the second region β, or the charged particle source side with respect to the electrode 1. In other words, the region corresponding to a difference between the internal diameter φ1 and the internal diameter φ2 of the first region (doughnut-shaped region in FIG. 1B) is the shield plate structure region having the shield plate function.

Here, the through hole 4 is illustrated as a through hole having two internal diameters, in which the shield plate structure region for blocking the scattered substances, the evaporated substances, or the like, of the sample is the first region α, and the region to which the scattered substances, the evaporated substances, or the like, of the sample should not adhere, is the second region β. Here, the through hole 4 may have other regions having an internal diameter or an opening contour different from the first region α or the second region β.

The reason why the above-mentioned shield plate structure region as the first region α has an effect of blocking the scattered substances, the evaporated substances, or the like, of the sample as the object to be irradiated by the charged particle beam, is that the scattered substances, the evaporated substances, or the like, are scattered linearly when the charged particle beam irradiates the object. The step of irradiating the object with the charged particle beam is performed in a vacuum or a low pressure atmosphere. Therefore, the scattered substances, the evaporated substances, or the like, are scattered radially and linearly from the position irradiated with the charged particle beam. Therefore, the shielding effect can be obtained by disposing the first region α on the straight line connecting the position irradiated with the charged particle beam and the second region β as the region to which the scattered substances, the evaporated substances, or the like, of the sample should not adhere (on the propagation path of the scattered substances, the evaporated substances, or the like).

Exemplary specific material and dimensions in this embodiment are described. The electrode 1 is made of single crystal silicon, or the like. A surface of the electrode 1 and a side wall of the through hole 4 may be covered with a conductive material film as necessary. As the conductive material, a material having good adhesiveness to silicon, high conductivity, and resistance to oxidization is selected. For instance, the conductive material is selected from titanium, platinum, gold, molybdenum, and the like. The electrode 1 has a total thickness of one hundred micrometers and is formed of a first region α having a thickness often micrometers and a second region β having a thickness of ninety micrometers. The internal diameter φ1 of the first region α is twenty micrometers, and the internal diameter φ2 of the second region β is thirty micrometers.

Next, a manufacturing method of this embodiment is described. First, a groove having an internal diameter of thirty micrometers and a depth of ninety micrometers is formed in a silicon substrate having a thickness of one hundred micrometers by photolithography technology and deep dry etching technology, to thereby form a region corresponding to the second region β. Next, using photolithography technology and dry etching technology, a through hole having an internal diameter of twenty micrometers is formed, to thereby form a region corresponding to the first region α. In this way, the electrode 1 can be formed. Here, it is also possible to manufacture at least one of the first region α and the second region β with a silicon on insulator (SOI) substrate by photolithography technology and deep dry etching technology, so as to form the electrode 1 by joining the regions by the use of a wafer bonding technique. In addition, it is also possible to form the through hole by patterning both sides of the silicon substrate using photolithography technology, and by etching both sides using dry or wet etching technology,

If the electrode 1 is manufactured by the steps of forming the first region α using an SOI substrate including a device layer having a thickness of ten micrometers, forming the second region β using a silicon substrate having a thickness of ninety micrometers, and joining the regions by the use of wafer bonding technique, an actual shape of the electrode 1 may be as illustrated in FIG. 5A. A chip 6 may occur in an edge portion, or a recess 7 may occur as a notch when the second region β is formed. In addition, in order to improve withstand voltage when the electrode is used as a lens, a rounding 8 may be formed in the edge portion. In those cases, as an intended target shape of the electrode, the first region a and the second region β are regarded as being in the range illustrated in FIG. 5A.

A description is given of a case wherein the through hole is formed, by patterning both sides of a silicon substrate having a thickness of one hundred micrometers using photolithography technology, and by etching both sides using dry or wet etching technology. In this case, the opening contour of the through hole may have a tapered shape as illustrated in FIG. 5B. Then, as illustrated in FIG. 5B, it is considered that a point having the smallest internal diameter is the first region α, and that a portion of or a whole region closer to the charged particle source with, respect to the first region α is the second region β.

In addition, there is another case as illustrated in FIG. 5C. Here, the first region α is formed using an SOI substrate including a device layer having a thickness often micrometers, and the second region β that determines optical performance of the lens is formed using another SOI substrate including a device layer having a thickness often micrometers. Then, the region between the first region α and the second region β is formed using a silicon substrate having a thickness of eighty micrometers, and the electrode 1 is manufactured by joining the regions. In this case, the first region α and the second region β are regarded as being in the range illustrated in FIG. 5C.

According to the embodiment described above, as the electrode for the objective lens to be used closest to the object to be irradiated by the charged particle beam, it is possible to realize an electrode including the first region having the shield plate function of preventing the scattered substances, the evaporated substances, or the like, of the sample from entering the second region or the charged particle source side with respect to the electrode.

### Second Embodiment

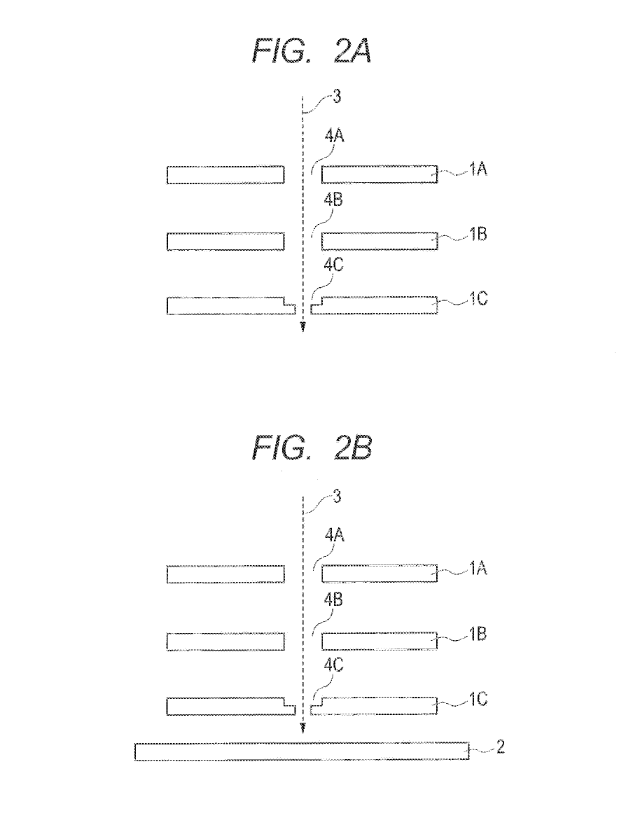

With reference to FIG. 2A, a second embodiment of the present invention is described. This embodiment is a charged particle beam objective lens using an electrode described in the first embodiment. A portion having the same function as that of the first embodiment is denoted by the same reference numeral or symbol, and an overlapping description thereof is omitted.

As illustrated in FIG. 2A, the charged particle beam objective lens of this embodiment includes three electrodes 1A, 1B, and 1C. The three electrodes are flat plates having the optical axis 3 as the normal and are electrically insulated from each other. The three electrodes have through holes 4A, 4B, and 4C, respectively, which transmit the charged panicles emitted from the charged particle source (not shown). The centers of the through holes 4A, 4B, and 4C are aligned along the optical axis direction. If each electrode has multiple through holes, corresponding through holes of the multiple electrodes are aligned along the optical axis direction. The charged panicles propagate in the direction of the arrow of the optical axis 3 and reach the sample (not shown). The electrode 1C is an electrode closest to the sample, for which the electrode of the first embodiment described above is used. Each of the three electrodes has at least one charge pad (not shown) so as to apply an electrical potential, and the electrical potential of each electrode is determined so that desired optical characteristics are expressed. For instance, the electrode 1A and the electrode 1C are set to the ground potential, and a negative voltage is applied to the electrode 1B. Thus, an Einzel-type electrostatic objective lens can be constituted.

In general, the performance of the electrostatic charged particle beam lens is determined by a shape of an electrostatic field formed in a region through which the charged particle beam passes. This corresponds to the electrostatic field formed in the regions of the through holes 4A to AC through which the charged particle beam passes, as illustrated in FIG. 2A. As the electrostatic field formed in this region becomes more rotationally symmetric about the optical axis 3, aberration of the charged particle beam lens becomes smaller, In the case of the electrostatic charged particle beam objective lens, the region of the electrostatic field particularly affecting the aberration is the region from the lower half of the through hole 4A to the upper half of the through hole 4C.

When the sample is irradiated by the charged particle beam, a material forming the sample surface, for example, an organic substance forming the resist is scattered and evaporated from the sample surface. The scattered substance and the evaporated substance from the sample surface adhere to a part of the objective lens close to the sample. When the scattered substance and the evaporated substance and the sample surface adhere to the objective lens, the electrostatic field formed in the objective lens is changed from an Initial state due to electrification, or the like. Then, aberration characteristics of the objective lens get worse.

In this embodiment the electrode having the shield plate structure on the sample side is used as the electrode 1C closest to the sample in tire objective lens. Thus, it is possible to suppress adhesion of Ore scattered substance and the evaporated substance from the sample surface to a portion of the lens particularly affecting aberration characteristics of the lens. The first region α having a function of blocking the scattered substance and the evaporated substance from the sample surface has very little influence to aberration characteristics of the lens. Therefore, in many cases, there is not a problem, even if the scattered, substance and the evaporated substance from the sample surface adhere to this portion. In addition, there is not a problem, even if the opening contour is made smaller than other parts.

Exemplary specific materials and dimensions in this embodiment are described. The first embodiment is applied to the electrode 1C. The electrodes 1A and 1B are made of single crystal silicon. A surface of each electrode and side walls of the through holes 4A and 4B may be covered with a conductive material film. As the conductive material, a material having good adhesiveness to silicon, high conductivity, and resistance to oxidization is selected. For instance, the conductive material is selected from titanium, platinum, gold, molybdenum, and the like. Each of the electrodes 1A and 1B has a thickness of one hundred micrometers. Each of the through holes 4A and 4B has an internal diameter of thirty micrometers. The electrodes 1A, 1B, and 1C are electrically insulated in the direction of the optical axis 3 and are disposed with spaces of four hundred micrometers each. The electrodes 1A, 1B, and 1C may be disposed via insulating glass or an insulating material. Electrical potentials can be applied to the electrodes 1A, 1B, and 1C, individually. For instance, −3.7 kV is applied to the electrode 1B, and the electrodes 1A and 1C are set to the ground potential. Thus, an Einzel-type electrostatic lens van be constituted,

Next, a manufacturing method of this embodiment is described. The first embodiment is applied to the electrode 1C. As to the electrodes 1A and 1B, the through holes 4A and 4B are formed in a silicon substrate having a thickness of one hundred micrometers by photolithography technology and silicon deep dry etching.

As described above, in the charged particle beam objective lens of this embodiment, the electrode having the shield structure is used as the electrode closest to the sample. Thus, it is possible to suppress adhesion of the scattered substances and the evaporated substances from the sample to the second region or the inside of the lens, which affect aberration characteristics, and to provide an electrostatic charged particle beam objective lens that hardly changes aberration characteristics even if the sample is irradiated with the charged particle beam for a long time.

### Third Embodiment

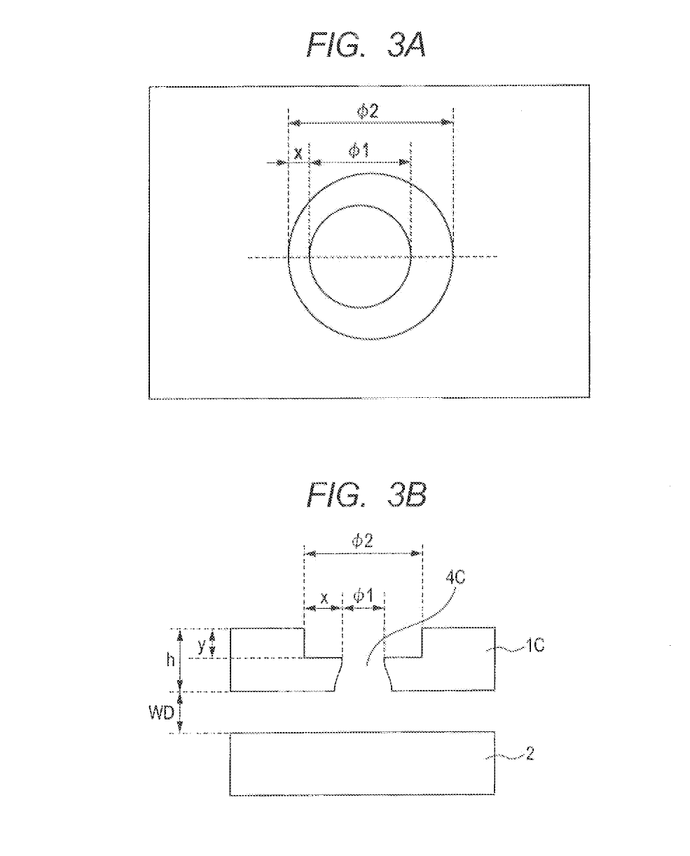

With reference to FIGS. 2B, 3A, and 3B, a third embodiment of the present invention is described. This embodiment shows an exemplary positional relationship between a shape of the electrode closest to the sample to be irradiated with the charged particle beam and the sample in a case wherein the charged particle beam objective lens is applied to the charged particle beam exposure equipment. A portion having the same function as the above-mentioned embodiments is denoted by the same reference numeral or symbol, and an overlapping description thereof is omitted.

FIG. 2B is a schematic cross-sectional view of the charged particle beam objective lens and its vicinity of the charged particle beam exposure equipment according to this embodiment. As illustrated in FIG. 2B, in the charged particle beam exposure equipment of this embodiment, a sample 2 is irradiated with, the charged particle beam passing through the through holes 4A, 4B, and 4C of the electrodes 1A, 1B, and 1C to reach the sample 2. When the sample 2 is irradiated with the charged particle beam, a material forming the sample surface, for example, an organic substance forming the resist is scattered linearly from the surface of the sample 2 at the portion irradiated with the charged particle beam. In the electrode 1C, the second region β is a portion having a large influence to the aberration characteristics of the objective lens. Therefore, if the second region β cannot be viewed directly from the sample 2, the scattered substance from the surface of the sample 2 can hardly adhere to the second region β.

The electrode 1C has a structure including the first region α and the second region β. There is a case wherein the center position of the through hole is shifted between the first region α and the second region β due to a manufacturing problem, such as misalignment in the photolithography step and the bonding step. Therefore, it is desired to design the shape of the electrode 1C and a relative positional relationship between the electrode IC and the sample 2 considering a positional shift in the manufacturing process. In particular, as the resolution of the patterning apparatus as the exposure equipment is increased more, the distance between the objective lens and the sample 2 becomes smaller. Therefore, the scattered substance from the sample surface, which is scattered when the sample is irradiated with the charged particle beam, is more likely to adhere to the objective lens. Therefore, it is very important to design the shape of the electrode IC and the relative positional relationship between the electrode IC and the sample 2 to meet a preferred condition,

FIG. 3A is a schematic plan view in which an internal diameter contour of the first region α and an internal diameter contour of the second region β of the electrode IC according to this embodiment are projected to the sample along the optical axis direction. In FIG. 3A, x represents a minimum space between the Internal diameter contour of the first region α and the internal diameter contour of the second region β.

FIG. 3B is an enlarged view of the through hole 4C and its vicinity of FIG. 2B. In FIG. 3B, h represents the thickness of the electrode IC in the optical axis direction, WD represents a space between the electrode IC and the sample 2 in the optical axis direction, φ1 represents the internal diameter of the first region α, and y represents a distance between the surface of the electrode IC on the charged particle source side and the first region α in the normal direction (optical axis direction).

The shape of the electrode 1C and the relative positional relationship between the electrode 1C and the sample 2 is set to the relationship expressed by the following inequality:

x/yφ1/(WD+h−y),

Thus, it is possible to provide a charged particle beam exposure equipment in which aberration characteristics of the objective lens are hardly changed even if the patterning is performed for a long time.

With the structure satisfying the relationship expression above, the second region β is not directly viewed from the sample 2 at all. Therefore, the scattered substances, the evaporated substances, or the like, of the sample, which may adhere to the second region β, can be blocked more appropriately by the first region α.

### Fourth Embodiment

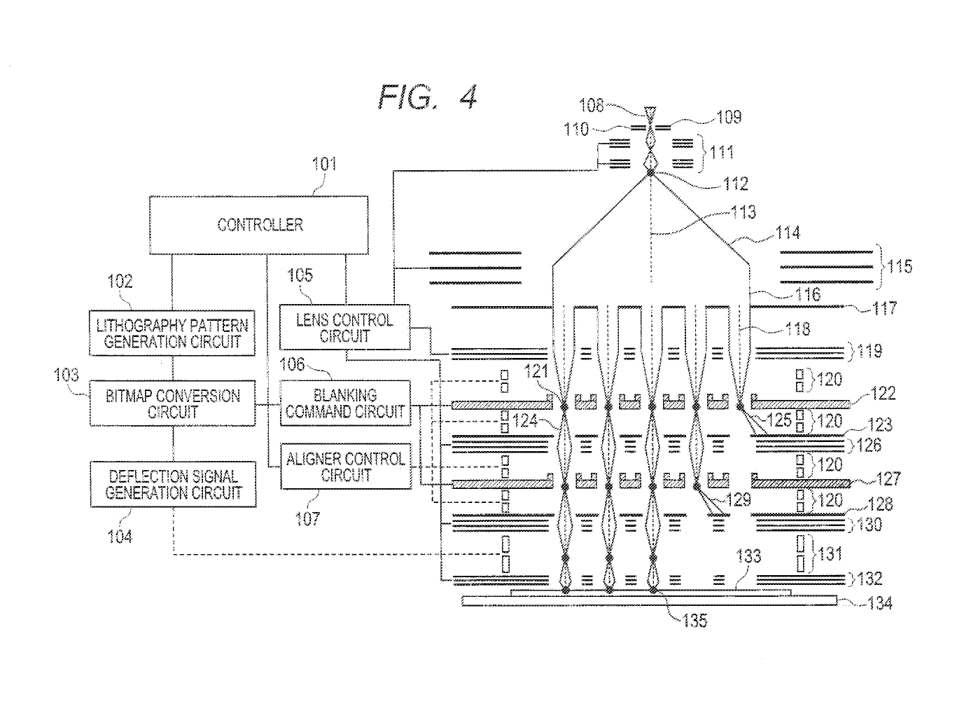

With reference to FIG. 4, a fourth embodiment of the present invention is described. This embodiment shows a charged particle beam exposure equipment using multiple charged particle beams. A portion having the same function as the above-mentioned embodiments is denoted by the same reference numeral or symbol, and an overlapping description thereof is omitted,

FIG. 4 is a diagram illustrating a structure of a multi-charged particle beam exposure equipment according to this embodiment. This embodiment is a so-called multi-column type exposure equipment having individual projection systems. The radiated electron beam emitted, from an electron source 108 as the charged particle source and attracted by anode electrodes 109 and 110 forms an irradiation optical system crossover 112 by a crossover adjustment optical system 111. Here, a so-called thermoelectron type electron source, such as LaB6 or BaO/W (dispenser cathode), is used as the electron source 108. The crossover adjustment optical system 111 includes a two-stage electrostatic lens. In both the first and second stages, the electrostatic lens is an Einzel-type electrostatic lens formed of three electrodes, in which a negative voltage is applied to the intermediate electrode, and the upper and lower electrodes are connected to the ground.

Electron beams 113 and 114 radiated in a wide range from the irradiation optical system crossover 112 are collimated by a collimator lens 115 to be parallel beams 116 to irradiate an aperture array 117. Multiple electron beams 118 split by the aperture array 117 are focused individually by a focus lens array 119 and form images on a blanker array 122. Here, the focus lens array 119 is an electrostatic lens including three multitude electrodes and is an Einzel-type electrostatic lens array controlled by a lens control circuit 105, in which a negative voltage is applied only to the intermediate electrode out of the three electrodes, and the upper and lower electrodes are connected to the ground. In addition, the aperture array 117 is disposed at a pupil plane position of the focus lens array 119 (front focal plane position of the focus lens array) so as to have a role to define a numerical aperture (NA) (convergence half angle). The blanker array 122 is a device having individual deflection electrodes and turns on and off the beams individually according to a lithography pattern based on a blanking signal generated by a lithography pattern generation circuit 102, a- bitmap conversion circuit 103, and a blanking command circuit 106. A voltage is not applied to the deflection electrode of the blanker array 122 when the beam is in an on state, while the voltage is applied to the deflection electrode of the blanker array 122 when the beam is in an off state, so as to deflect the multiple electron beams. Multiple electron beams 125 deflected by the blanker array 122 are blocked by a stop aperture array 123 disposed in a post stage (on the downstream side) so that the beams become the off state. Multiple aligners 120 are controlled by an aligner control circuit 107 so as to adjust an incident angle and an incident position of the electron beam. In addition, a controller 101 controls the entire circuit.

In this embodiment, the blanker array has two stages, in which a second blanker array 127 and a second stop aperture array 128 having the same structures as that of the blanker array 122 and the stop aperture array 123 are disposed in the post stage. The multiple electron beams after passing through the blanker array 122 form images on the second blanker array 127 by a second focus lens array 126. Further, the multiple electron beams are focused by third and fourth focus lenses so as to form images on a wafer 133. Here, the second focus lens array 126, a third focus lens array 130, and a fourth focus lens array 132 are Einzel-type electrostatic lens arrays, similar to the focus lens array 119.

In particular, the fourth focus lens array 132 is the objective lens, and a reduction ratio thereof is set to approximately one hundred. Thus, an electron beam 121 (having a spot diameter of two micrometers in FWHM) on an intermediate image formation plane of the blanker array 122 is reduced to 1/100 on the surface of the wafer 133 so that images of the multiple electron beams having a spot diameter of approximately twenty nm in FWHM are formed on the wafer. Each through hole of the fourth focus lens array 132 has the above-mentioned shield plate structure (not shown) according to the present invention. Therefore, the scattered substance and tire evaporated substance from the surface of the wafer 133 are prevented from adhering to a portion of the fourth focus lens array 132 that strongly affects the objective lens characteristics. Scanning of the wafer 133 by the multiple electron beams can be performed by a deflector 131. The deflector 131 is formed of opposing electrodes. In order to perform two-stage deflection in the X and Y directions, four-stage opposing electrodes are disposed- (FIG. 4 illustrates two-stage deflectors as one unit for simple illustration.) The deflector 131 is driven by a signal of a deflection signal generation circuit 104.

The wafer 133 is moved continuously in the X direction by a stage 134 during the patterning. Then, based on a result of measurement in actual tune by a laser rangefinder, an electron beam 135 on the wafer surface is deflected in the Y direction by the deflector 131, and the beams are turned, on and off individually according to the lithography pattern by the blanker array 122 and the second blanker array 127. A beam 124 indicates the on beam, and beams 125 and 129 indicate off beams. Thus, a desired pattern can be patterned on the surface of the wafer 133 at high speed in a short patterning time. As described above, the multi-charged particle beam exposure equipment according to this embodiment includes the electrostatic charged particle beam objective lens of the present invention, and multiple charged particle beams from the charged particle source pass through multiple through holes of the electrode of the objective lens and irradiate the object. In this way, by using multiple charged particle beams for patterning, it is possible to provide a charged particle beam exposure equipment that can be used with high throughput for a long time.

While the present invention has been described with reference to exemplary embodiments, it is to be understood that the invention is not limited to the disclosed exemplary embodiments. The scope of the following claims is to be accorded the broadest interpretation so as to encompass all such modifications, and equivalent structures and functions.

1. An electrode to be used for an electrostatic charged particle beam lens, the electrode comprising:
at least one through hole,
wherein the at least one through hole includes a first region having a first opening contour and a second region having a second opening contour to be positioned on an upstream side of a charged particle beam with respect to the first region, and the first opening contour is included in the second opening contour when viewed in an optical axis direction.

2. The electrode according to claim 1, wherein the at least one through hole has a circular cross section, and the first region of the at least one through hole has a first internal diameter, and the second region of the at least one through hole has a second internal diameter that is larger than the first internal diameter.

3. An electrostatic charged particle beam lens comprising:
at least one electrode including at least one through hole,
wherein the at least one electrode comprises the electrode according to claim 1 as an electrode that is positioned closest to an object to be irradiated with the charged particle beam.

4. The electrostatic charged particle beans lens according to claim 3, wherein the following expression is satisfied:
x/yφ1/(WD+h−y),
where x represents a minimum space between an internal diameter contour of the first region of the electrode disposed closest to the object and an internal diameter contour of the second region thereof h represents a thickness of the electrode in the optical axis direction, WD represents a space between the electrode and the object in the optical axis direction, φ1 represents an internal diameter of the first, region, and y represents a distance from a surface of the electrode on the upstream side of the charged particle beam to the first region in the optical axis direction, when the first opening contour of the first region and the second opening contour of the second region are projected onto the object to be irradiated by the charged particle beam along the optical axis direction.

5. The electrostatic charged particle beam lens according to claim 3, comprising multiple electrodes, each of which includes multiple through holes through which, charged particle beams are transmitted,
wherein corresponding through holes of the multiple electrodes are aligned along the optical axis direction.

6. A charged particle beam exposure equipment comprising:
the electrostatic charged particle beam lens according to claim 3, wherein an object is irradiated with a charged particle beam, from a charged particle source while the charged particle beam passes through a through hole of an electrode of the electrostatic charged particle beam lens.
